(19) United States
(12) Patent Application Publication
(10) Pub. No.: US 2006/0238782 A1
(43) Pub. Date: Oct. 26, 2006

(54) Image multitoning apparatus to minimize dot overlap and method thereof

(76) Inventor: Sang-ho Kim, Suwon-si (KR)

Correspondence Address: STANZIONE & KIM, LLP, 919 18TH STREET, N.W., SUITE 440, WASHINGTON, DC, 20006, US

(21) Appl. No.: 11/288,312

(22) Filed: Nov. 29, 2005

(30) Foreign Application Priority Data
Apr. 22, 2005 (KR) 2005-33574

(51) Int. Cl. G03F 3/08; G06F 15/00

(52) U.S. Cl. 358/1.9; 358/518; 358/3.06

(57) ABSTRACT

An image multitoning device to minimize dot overlap includes a color component divider to generate color component images from a CMYK color image received from an image source, a halftoning processor to perform multi-level halftoning on the color component images and to generate halftone images corresponding to the color component images, and a print engine unit to adaptively arrange dots corresponding to CMYK color components according to the halftone images so that in each pixel overlap of the dots is minimized.

### CROSS-REFERENCE TO RELATED APPLICATIONS

This application claims the benefit under 35 U.S.C. § 119 of Korean Patent Application No. 2005-33574, filed in the Korean Intellectual Property Office on Apr. 22, 2005, the entire content of which is incorporated herein by reference.

### BACKGROUND OF THE INVENTION

1. Field of the Invention

The present general inventive concept relates to an image multitoning apparatus and method, and more particularly, to an image multitoning apparatus and method which are capable of obtaining a print output with high picture quality by minimizing dot-on-dot printing of dots corresponding to CMYK color components (C represents cyan, M represents magenta, Y represents yellow, and K represents black).

2. Description of the Related Art

In general, binary output devices, such as a digital printer, a copier, a binary output LCD, etc., represent various color tones using only two colors, black and white. For example, a black-and-white digital printer represents a black-and-white image displayed on a monitor using two values of black and white. In order to print a black-and-white image having various ranges of brightness displayed on a monitor through a black-and-white printer, the printer or a corresponding PC should perform a process of converting an input image into a binary image. That is, an operation of converting a color of each pixel into a gray-scale image represented by a brightness value between 0 and 255, and an operation of converting the gray-scale image into a binary image are required. Here, the gray-scale image having the brightness value between 0 (black) and 255 (white) is called a gray-level image and the operation of converting the gray-level image into the binary image is called “halftoning.”

Conventionally, a binary halftoning technique of representing only two gray-levels through on/off of dots has been mainly used. However, recently, along with the development of new hardware technologies, an N-bit color multi-level halftoning technique of representing two-or-more gray-level values has been implemented.

The N-bit color multi-level halftoning technique can represent 2^{N} gray-levels. When the N-bit color multi-level halftoning technique is used, an inkjet printer represents two-or-more gray-levels by adjusting a drop size of ink, and a laser printer represents the two-or-more gray-levels by adjusting a laser pulse width or power.

A print method based on a conventional N-bit color multi-level halftoning technique is described bellow. A CMYK color image received from an image source is divided into 8 bit CMYK color components. That is, the CMYK color image includes 32-bit color information for each pixel, with 8 bits allocated to each of four CMYK colors. A cyan (C) color component, a magenta (M) color component, a yellow (Y) color component, and a black (K) color component having 8-bit color components representing color values are separated from the 32-bit color information. Multi-level halftoning is performed on the respective CMYK color components. By performing the multi-level halftoning, halftone images having N-bit color values are created, and a pulse width and a pulse offset are calculated based on the N-bit color values of the halftone images. That is, each N-bit color value in a halftone image corresponds to an 8-bit color value in a corresponding color component. A dot is formed during printing for each pixel and each color according to the N-bit color value. Conventionally, dots corresponding to the color components are arranged in respective pixels by overlapping (dot-on-dot) according to the pulse offset and pulse width and then a print job is performed.

FIG. 1 illustrates a dot position in a pixel lattice according to a pulse width “a” and a pulse offset “b” in a conventional N-bit color multi-level halftoning technique. As illustrated in FIG. 1, the dot is arranged according to the pulse offset “a” and the pulse width “b” calculated based on the N-bit color values of the halftone images. Conventionally, the pulse width “b” is determined by the N-bit color value in the halftone image and the pulse offset “a” is calculated to place the dot in a center of a cell of a pixel lattice.

FIG. 2 is a view illustrating an example of a multicolor image where dots corresponding to the color components overlap with each other when a conventional multi-level color printing method is used. Referring to FIG. 2, dots corresponding to respective color components are printed to overlap with each other. As such, if the dots corresponding to the color components overlap and are printed to obtain a final print output, the print output appears noisy and picture quality deteriorates as a result of a reduction in the clarity of colors due to interference between the color components.

### SUMMARY OF THE INVENTION

The present general inventive concept provides an image multitoning apparatus and method which are capable of minimizing dot-on-dot printing of dots corresponding to CMYK color components in an output image to thus obtain a print output with high picture quality.

Additional aspects of the present general inventive concept will be set forth in part in the description which follows and, in part, will be obvious from the description, or may be learned by practice of the general inventive concept.

The foregoing and/or other aspects of the present general inventive concept may be achieved by providing an image multitoning device including a color component divider to separate 8 bits of CMYK color components from a CMYK color image received from an image source, a halftoning processor to perform multi-level halftoning on the 8 bits of CMYK color components and to generate halftone images, wherein each color value in the halftone images is an N-bit value for CMYK colors, and a print engine unit to adaptively arrange dots corresponding to CMYK colors according to the halftone images so that an overlap of the dots in each pixel in minimized.

The print engine unit may include a color component number determination unit to determine a number of the CMYK colors to be arranged in each pixel according to the halftone images, a pulse width calculator to calculate pulse widths of the CMYK colors to be arranged in each pixel according to the N-bit color values of the halftone images, a pulse offset calculator to adaptively calculate pulse offsets of the CMYK colors to be arranged in each pixel enabling an arrangement of the dots so that the overlap of the dots in each pixel is minimized, based on the number of the CMYK colors to be arranged in each pixel and the calculated pulse widths thereof, and an engine controller to arrange the dots corresponding to the CMYK colors in each pixel according to the calculated pulse widths and the calculated pulse offsets.

The image multitoning device may further include a print unit to print the dots corresponding to the CMYK colors which are adaptively arranged in each pixel.

If the color component number determination unit determines that at least three colors of the four possible CMYK colors exist in a pixel, the pulse offsets may be adaptively calculated so that dots corresponding to the at least three colors are positioned to minimize the overlap of the dots in the pixel according to positions of in an order of the colors and the calculated pulse widths of the at least three colors.

The order of the four possible CMYK colors may be one of K-M-C-Y and K-C-M-Y and K represents black, M represents magenta, C represents cyan, and Y represents yellow.

If the color component number determination unit determines that a single color of the four possible CMYK colors exists in a pixel, a dot corresponding to the single color may be formed in a center of the pixel.

N may be an integer greater than 1 and less than 8.

The color component divider and the halftoning processor may comprise firmware in an image forming apparatus.

The color component divider and the halftoning processor may be implemented in a host device.

The foregoing and/or other aspects of the present general inventive concept may also be achieved by providing an image multitoning method including separating 8 bits of CMYK color components from a CMYK color image received from an image source, performing multi-level halftoning on the 8 bits of CMYK color components and generating corresponding halftone images having N-bit color values for CMYK colors, and adaptively arranging dots corresponding to the halftone images so that an overlap of the dots is minimized in each pixel.

The arranging of the dots corresponding to the halftone images includes determining the number of the CMYK colors to be arranged in each pixel according to the halftone images, calculating pulse widths according to the N-bit color values of the halftone images, adaptively calculating pulse offsets to enable an arrangement of the dots corresponding to the color components so that the overlap of the dots is minimized in each pixel, based on the determined number of the CMYK colors and the calculated pulse widths, and arranging the dots corresponding to the CMYK colors in each pixel according to the calculated pulse widths and the calculated pulse offsets.

If it is determined that at least three colors of the four CMYK colors exist in a pixel, the pulse offsets may be adaptively calculated so that the dots corresponding to the at least three colors are positioned to minimize the overlap of the dots in the pixel and positions of the dots in an order of the colors and the calculated pulse widths of the at least three colors.

The predetermined order of the four CMYK colors may be one of K-M-C-Y and K-C-M-Y.

If a single color component of the four CMYK colors exists in a pixel, a dot corresponding to the single color component is formed in a center of the pixel.

N may be an integer greater than 1 and smaller than 8.

The foregoing and/or other aspects of the present general inventive concept may also be achieved by providing an image processing module module to convert a color input image into printing information, the module comprising a color component separator to generate color component images from the color input image, each color component image corresponding to a printing color of a printer, a color intensity conversion unit to convert color values of the color component images into first printing information used to determine sizes of dots of the respective printing colors to be arranged in printing cells, and a color arranging unit to calculate second printing information used to determine an arrangement of the dots in each printing cell so that an overlap of the dots is minimized.

The foregoing and/or other aspects of the present general inventive concept may also be achieved by providing a dot arranging unit to determine positions of dots corresponding to printing colors in a cell of a pixel lattice, the dot arranging unit comprising a positioning module to calculate parameters controlling positions of centers of the dots in the cell based on sizes of the dots and a number of dots to be positioned in the cell so that to minimize an overlap of the dots.

The foregoing and/or other aspects of the present general inventive concept may also be achieved by providing an image multitoning apparatus comprising a color component divider to divide an input color image into at least two color component layers corresponding to printing colors, the apparatus comprising a color component divider to divide an input color image into at least two color component layers corresponding to printing colors, a halftone processor to convert the at least two color component layers into corresponding halftone images comprising color values within a range of color levels, and a printing engine to calculate sizes of color dots to be printed according to the halftone images, and to calculate color dot position of the color dots based on the sizes of the color dots sizes such that an overlap of the color dots is minimized.

The foregoing and/or other aspects of the present general inventive concept may also be achieved by providing a method of converting a color input image into printing information, the method including generating color component images from the color input image, each color component image corresponding to a printing color of a printer, converting color values of the color component images into first printing information used to determine sizes of dots of the respective printing color to be arranged in printing cells, and calculating second printing information used to determine an arrangement of the dots in each printing cell so that an overlap of the dots is minimized.

The foregoing and/or other aspects of the present general inventive concept may also be achieved by providing a method of minimizing color dots overlapping in a color printer, the method including calculating parameters controlling positions of centers of color dots in printing cells of a pixel lattice based on sizes of the color dots so that to minimize an overlap of the color dots.

The foregoing and/or other aspects of the present general inventive concept may also be achieved by providing a computer readable medium having executable codes to perform a method to minimize an overlap of color dots in a printing output, the method comprising dividing an input color image into at least two color component layers corresponding to printing colors, converting the at least two color component layers into corresponding halftone images comprising color values within a range of color levels, and calculating sizes of color dots to be printed according to the halftone images and to calculate color dot positions of the color dots based on the sizes of the color dots such that an overlap of the color dots is minimized.

The foregoing and/or other aspects of the present general inventive concept may also be achieved by providing an image forming apparatus, comprising a print unit to print data, and an image multitoning appataus in communication with the print unit to divide input color image into at least two color component layers corresponding to printing colors, to convert the at least two color component layers into corresponding halftone images comprising color values within a range of color levels, to calculate sizes of color dots to be printed according to the halftone images and to calculate color dot positions of the color dots based on the sizes of the color dots such that an overlap of the color dots is minimized, and to output printing data with the positioned color dots to the print unit.

### BRIEF DESCRIPTION OF THE DRAWINGS

These and/or other aspects of the present general inventive concept will become apparent and more readily appreciated from the following description of the embodiments, taken in conjunction with the accompanying drawings of which:

FIG. 1 is a view illustrating a dot position in a pixel lattice according to a pulse width and a pulse offset in a conventional N-bit color multi-level halftoning technique.

FIG. 2 is a view illustrating dots overlapping in a pixel when a conventional multi-level color printing method is used.

FIG. 3 is a view illustrating an image multitoning apparatus to minimize dot overlap according to an embodiment of the present general inventive concept.

FIG. 4 is a block diagram of a print engine unit of the image multitoning apparatus illustrated in FIG. 3 according to an embodiment the present general inventive concept.

FIG. 5 is a flowchart illustrating an image multitoning method of minimizing dot overlap according to an embodiment of the present general inventive concept.

FIG. 6 illustrates an example of a dot arrangement in a pixel when using the image multitoning method of FIG. 5 according to an embodiment of the present general inventive concept.

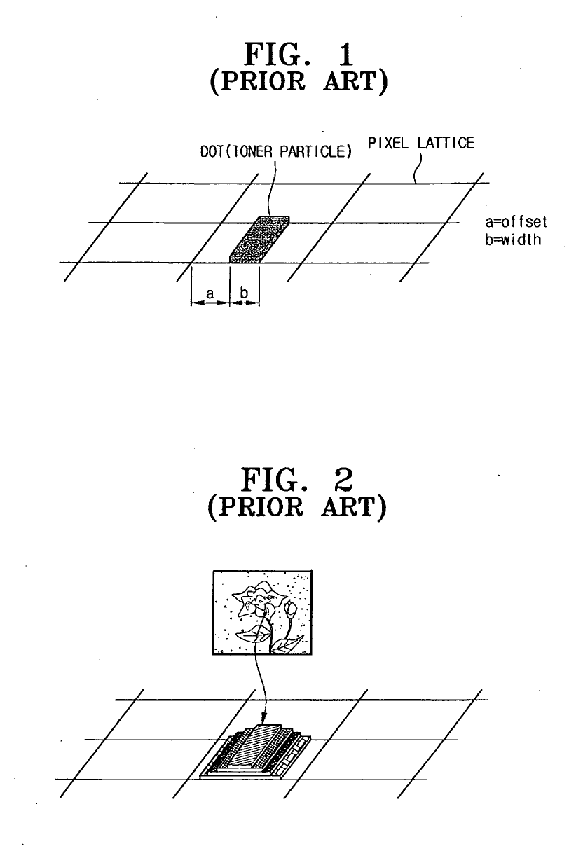

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

FIG. 3 illustrates an embodiment of an image multitoning apparatus 300 to minimize dot overlap according to the present general inventive concept. Referring to FIG. 3, the image multitoning apparatus 300 includes a color component divider 310, a halftoning processor 320, and a print engine unit 330. The image multitoning apparatus 300 may be an image forming apparatus, such as a printer. Alternatively, the image multitoning apparatus 300 may be a component of an image forming apparatus or may be separate from the image forming apparatus. The color component divider 310 and the halftoning processor 320 can be implemented as firmware in an image forming apparatus. When host-based printing is used, the color component divider 310 and the halftoning processor 320 can be implemented in a host device, such as a computer, which can communicate with an image forming apparatus.

The color component divider 310 separates 8 bits of CMYK color components from a CMYK color image received from an image source and provides the respective color components to the halftoning processor 320. Here, the color components correspond to cyan (C), magenta (M), yellow (Y), and black (K). Although the description of the present general inventive concept refers to processing a CMYK input color image, it should be understood that this description is not intended to limit the scope of the present general inventive concept and is merely exemplary. That is, an input image according to different color schemes and color components may be processed in the same manner as the CMYK color image mentioned above and described hereinafter. Additionally, although the color components are described as having 8-bit values, it should be understood that the color components may have more or less bits.

The halftoning processor 320 performs multi-level halftoning on the respective 8 bits of each of the CMYK color components, to create halftone images including N-bit color values, and provides the halftone images to the print engine unit 330. Here, N is an integer greater than 1 and smaller than 8. In halftoning-based printing, since the halftone images are created in a host device, the halftone images are transmitted to the print engine unit 330 in the image forming apparatus through a printer interface.

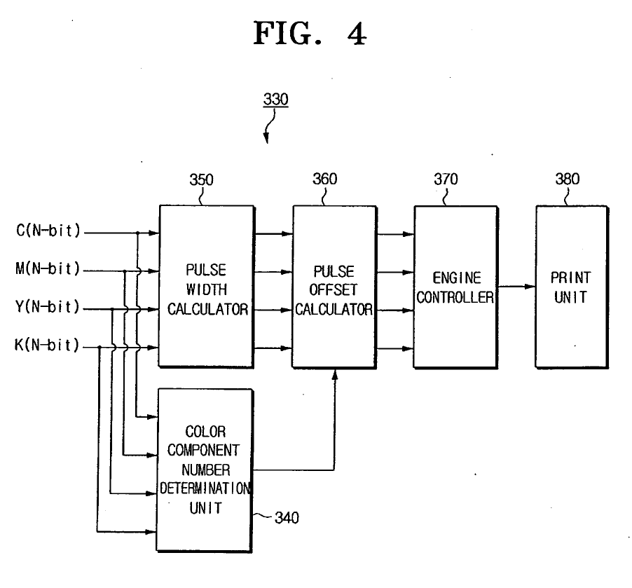

FIG. 4 is a block diagram representing the print engine unit 330 of the image multitoning apparatus 300 illustrated in FIG. 3. Referring to FIG. 4, the print engine unit 330 includes a color component number determination unit 340, a pulse width calculator 350, a pulse offset calculator 360, an engine controller 370, and a printing unit 380.

The color component number determination unit 340 determines a number of CMYK colors to be arranged in each pixel based on the halftone images received from the halftoning processor 320. The color component number determination unit 340 may count a color in a pixel if according to a corresponding color value in the pixel of a halftone image, the pulse width is not zero. Different dot arrangements can be implemented according to the number of CMYK colors when at least three color components of four possible CMYK color components exist (have corresponding non-zero widths) in the pixel and when two or less color components of the four possible CMYK color components exist in the pixel.

The pulse width calculator 350 and the pulse offset calculator 360 calculates pulse widths and pulse offsets corresponding to the CMYK colors adaptively based on the received halftone images. The pulse width calculator 350 calculates pulse widths based on the N-bit color values of each color component in the halftone images. The pulse offset calculator 360 adaptively calculates optimal pulse offsets to allow dots corresponding to the CMYK colors to be positioned as far away from each other as possible, thereby minimizing overlapping (dot-on-dot) by considering the calculated pulse widths and the number of the CMYK color components. As such, the dots corresponding to respective CMYK colors are positioned as far away from each other as possible to minimize dot-on-dot printing and thus obtain a print output having clear and soft color tones.

The engine controller 370 positions dots corresponding to the halftone images in corresponding pixels based on the calculated pulse offsets and pulse widths. The engine controller 370 controls the printing unit 360 to print the dots corresponding to the halftone images in the respective pixels.

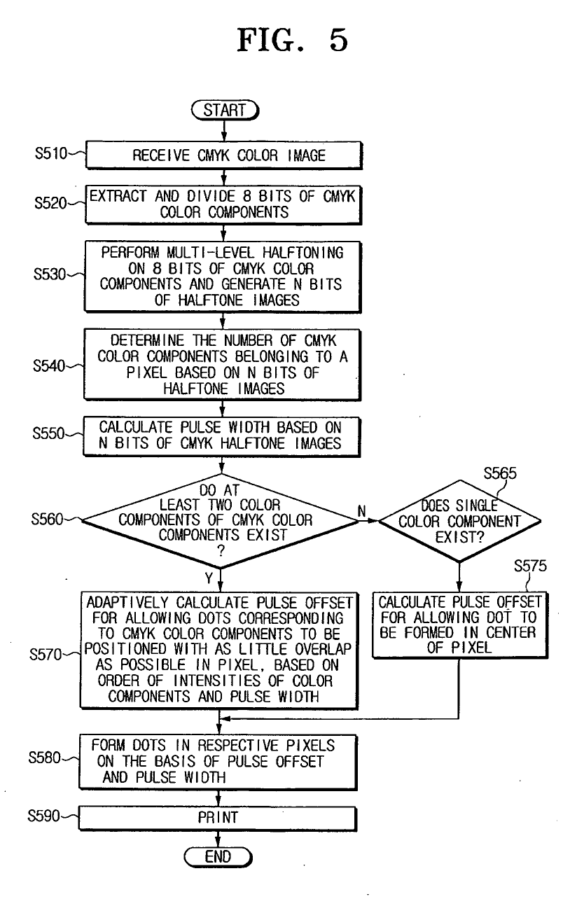

FIG. 5 is a flowchart illustrating an image multitoning method of minimizing dot overlap, according to an embodiment of the present general inventive concept. The method of FIG. 5 may be performed by the image forming apparatus of FIG. 3. Accordingly, the method of FIG. 5 is described with reference to FIGS. 3 through 5. Referring to FIGS. 3, 4 and 5, a CMYK color image output from an image source is input to the color component divider 310 (operation S510). The color component divider 310 separates 8 bits of CMYK color components from the input CMYK color image (operation S520).

The halftoning processor 320 then performs multi-level halftoning on the 8 bits of the CMYK color components and creates halftone images corresponding to each component color (operation S530). The halftone images have N-bit color values. The color component number determination unit 340 determines the number of CMYK color components of each pixel based on the halftone images received from the halftoning processor 320 (operation S540).

Once the number of CMYK color components of each pixel is determined in the operation S540, the pulse width calculator 350 calculates pulse widths of color dots to be printed in each pixel based on the N-bit color values of the halftone images (operation S550). For example, when the number of bits N of the color values of the halftone images is 2, a process of obtaining a pulse width is described below. In this case, 2² binary gray-levels [00], [01], [10], and [11] can be represented.

The binary gray-level [00] represents a case in which no dot having the respective color is formed in a pixel, and a pulse width corresponding to the binary gray-level data [00] is 0. The remaining binary gray-level data [01], [10] and [11] correspond to cases when dots having the respective color are formed in pixels. Accordingly, since the dots corresponding to three binary gray-level data [01], [10] and [11] are formed in the pixels, a pulse width of a dot corresponding to the binary gray-level data [11] may be “3b”, and pulse widths of dots corresponding to the binary gray-level data [10] and [01] may be “2b” and “b”, respectively. A color exists in the pixel if the pulse width of the dot of the color in the pixel is not zero.

If it is determined in the operation S540 that at least two colors of the four possible CMYK colors exist in the pixel (operation S560), the pulse offset calculator 360 calculates pulse offsets to arrange the dots corresponding to the at least two colors with as little overlap as possible in the pixel, according to an order of the color dots and the pulse widths of the color dots (operation S570). The engine controller 370 then arranges the color dots in the respective pixels based on the calculated pulse offsets and pulse widths (operation S580).

Here, the order of the color dots may be a predetermined order, such as K-M-C-Y or K-C-M-Y. Colors have associated priorities according to the order of the color dots. For example, when the order of the color dots is K-M-C-Y, black (K) has highest priority and yellow (Y) has lowest priority, while magenta (M) has higher priority than cyan (C). The order of the colors may be determined by N-bit color values in the halftone images. For example if N is 2, and black according to the halftone image has an associated value [11] while yellow according to the halftone image has an associated value [10], black has higher priority for the pixel. Other orders of the color dots may be used. When all CMYK colors exist (i.e. have non-zero pulse widths), an example in which dots are arranged in the order of K-M-C-Y is described below. First, dots corresponding to a black (K) color component and a magenta (M) color component are positioned as distant as possible. That is, a dot corresponding to the black (K) color component is formed on a left side of a pixel cell in a pixel lattice and a dot corresponding to the magenta (M) color component is formed on a right side of the pixel cell. In the same manner, dots respectively corresponding to a cyan (C) color component and a yellow (Y) color component are then positioned as far away from each other as possible. That is, a dot corresponding to the cyan (C) color component is formed on the left side of the pixel cell and a dot corresponding to the yellow (Y) color component is formed on the right side of the pixel cell.

Likewise, when two colors of the four possible CMYK colors exist in the pixel, pulse offsets are adaptively calculated considering the pulse widths of the two color components so that dots of the two color components are positioned with as little overlap as possible in the pixel to prevent a dot overlap, and the dots are arranged according to the pulse offsets. For example, if black (K) and yellow (Y) of the four possible CMYK colors exist in the pixel, the pulse offset calculator 360 adaptively calculates a first pulse offset has to place a dot corresponding to the black (K) color which has a highest priority to be formed on the left side of the pixel cell of a pixel lattice, and a second pulse offset to place a dot corresponding to the yellow (K) color which has a lower priority to be formed on the right side of the pixel cell (according to the order K-M-C-Y of the color dots), so that the dots corresponding to the two color components are positioned with as little overlap as possible in the pixel. Accordingly, the engine controller 370 arranges the dots in the respective pixels on the basis of the calculated pulse offset and pulse widths (operation S580).

When a single color of the four possible CMYK colors exists in the pixel (operation S565), the pulse offset calculator 360 calculates a pulse offset to form a dot corresponding to the single color in the center of the pixel cell of a pixel lattice, without concern for dot overlap (operation S575). Then, the engine controller 370 forms the dot corresponding to the color in the center of the pixel cell according to the calculated pulse width and pulse offset (operation S580).

If the dots are adaptively formed at calculated locations in each pixel cell of the pixel lattice according to the pulse width and pulse offset in the operation S580, the printing unit 380 prints all of the dots in the pixel lattice, thereby outputting a printed image corresponding to the input CMYK color image on a print sheet (operation S590).

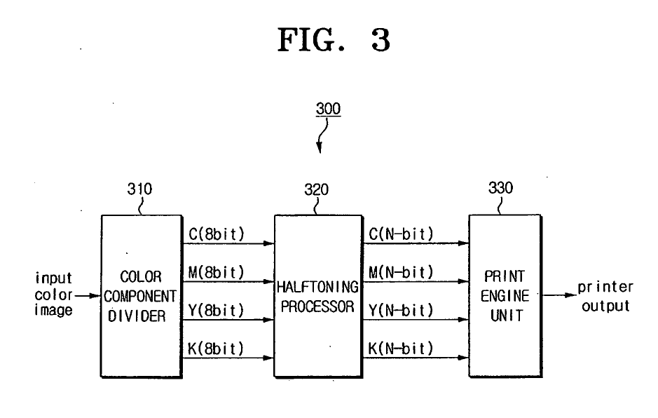

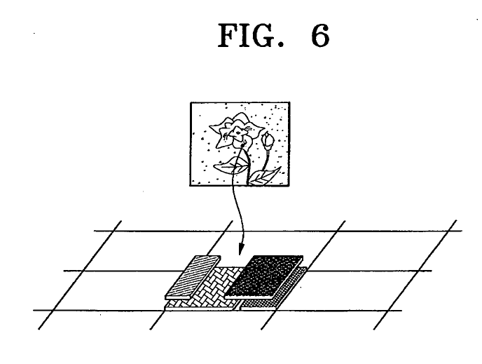

FIG. 6 illustrates an example of dots arranged in a pixel when performing the image multitoning method of FIG. 5 according to the present general inventive concept. Comparing FIG. 6 with FIG. 2, the overlap of dots corresponding to respective CMYK color components in each pixel is significantly reduced in FIG. 6 where the image multitoning method of minimizing dot overlap has been performed.

The embodiments of the present general inventive concept can be embodied in software, hardware, or a combination thereof. In particular, some embodiments can be computer programs and can be implemented in general-use digital computers that execute the programs using a computer readable recording medium. Examples of the computer readable recording medium include magnetic storage media (e.g., ROM, floppy disks, hard disks, etc.), optical recording media (e.g., CD-ROMs, DVDs, etc.), and storage media such as carrier waves (e.g., transmission through the internet). The computer readable recording medium can also be distributed over network coupled computer systems so that the computer programs are stored and executed in a distributed fashion.

As described above, according to the present general inventive concept, since dot-on-dot (overlap) printing of dots corresponding to CMYK colors is minimized, a print output has clear and soft color tones.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An image multitoning device comprising:
a color component divider to separate 8 bits of CMYK color components from a CMKY color image received from an image source;
a halftoning processor to perform multi-level halftoning on the 8 bits of CMYK color components and to generate halftone images, wherein each color value in the halftone images is an N-bit value for CMYK colors; and
a print engine unit to adaptively arrange dots corresponding to the CMYK colors according to the halftone images so that in each pixel an overlap of the dots is minimized.

2. The image multitoning device of claim 1, wherein the print engine unit comprises:
a color component number determination unit to determine a number of the CMYK colors to be arranged in each pixel according to the halftone images;
a pulse width calculator to calculate pulse widths of the CMYK colors to be arranged in each pixel according to the N-bit color values of the halftone images;
a pulse offset calculator to adaptively calculate pulse offsets of the CMYK colors to be arranged in each pixel enabling an arrangement of the dots that the overlap in each pixel is minimized, based on the number of the CMYK colors to be arranged in each pixel and the pulse widths thereof; and
an engine controller to arrange the dots corresponding to the CMYK colors in each pixel according to the calculated pulse widths and the calculated pulse offsets.

3. The image multitoning device of claim 2, further comprising:
a print unit to print the dots corresponding to the CMYK colors which are adaptively arranged in each pixel.

4. The image multitoning device of claim 2, wherein, if the color component number determination unit determines that at least three colors of four possible CMYK colors exist in a pixel, the pulse offsets are adaptively calculated so that dots corresponding to the at least three color components are positioned to minimize the overlap of the dots in the pixel and the dots positions are calculated according to an order of the colors and the calculated pulse widths of the at least three color components.

5. The image multitoning device of claim 4, wherein the order of the four possible CMYK colors is one of K-M-C-Y and K-C-M-Y, and K represents black, M represents magenta, C represents cyan, and Y represents yellow.

6. The image multitoning device of claim 2, wherein if the color component number determination unit determines that a single color of four possible CMYK colors exists in a pixel, a dot corresponding to the single color component is formed in a center of a cell of the pixel in a pixel lattice.

7. The image multitoning device of claim 2, wherein N is an integer greater than 1 and less than 8.

8. The image multitoning device of claim 1, wherein the color component divider and the halftoning processor comprise firmware in an image forming apparatus.

9. The image multitoning device of claim 1, wherein, the color component divider and the halftoning processor are implemented in a host device.

10. An image multitoning method comprising:
separating 8 bits of CMYK color components from a CMYK color image received from an image source;
performing multi-level halftoning on the 8 bits of CMYK color components and generating corresponding halftone images including N-bit color values for CMYK colors; and
adaptively arranging dots corresponding to the halftone images so that an overlap of the dots is minimized in each pixel.

11. The image multitoning method of claim 10, wherein the arranging of the dots corresponding to the halftone images comprises:
determining the number of the CMYK colors to be arranged in each pixel according to the halftone images;
calculating pulse widths according to the N-bit color values of the halftone images;
adaptively calculating pulse offsets to enable an arrangement of the dots corresponding to the CMYK colors so that the overlap of the dots in each pixel is minimized, based on the determined number of the CMYK colors in each pixel and the calculated pulse widths; and
arranging the dots corresponding to the CMYK colors in each pixel according to the calculated pulse widths and the calculated pulse offsets.

12. The image multitoning method of claim 11, wherein, if at least three colors of the four possible CMYK colors exist in a pixel, the pulse offsets are adaptively calculated so that the dots corresponding to the at least three colors are positioned to minimize the overlap of the dots in each pixel, according to an order of the CMYK colors and the calculated pulse widths of the dots on the at least three colors in the pixel.

13. The image multitoning method of claim 12, wherein the order of the CMYK colors is one of K-M-C-Y and K-C-M-Y, and K represents black, M represents magenta, C represents cyan, and Y represents yellow.

14. The image multitoning method of claim 11, wherein if it is determined that a single color of the four possible CMYK colors exists in a pixel, a dot corresponding to the single color is formed in a center of a pixel cell in a pixel lattice.

15. The image multitoning method of claim 10, wherein N is an integer greater than 1 and less than 8.

16. An image processing module to convert a color input image into printing information, the module comprising:
a color component separator to generate color component images from the color input image, each color component image corresponding to a printing color of a printer;
a color intensity conversion unit to convert color values of the color component images into first printing information used to determine sizes of dots of the respective printing colors to be arranged in printing cells; and
a color arranging unit to calculate second printing information used to determine an arrangement of the dots in each printing cell so that an overlap of the dots is minimized.

17. The image processing module of claim 16, wherein the color input image has color values corresponding to the printing colors and the color component separator divides the color values into individual printing color values to generate the color component images.

18. The image processing module of claim 17, wherein the color intensity conversion unit converts the individual printing color values of each of the color component images into color bit levels supported by the printer, and converts the color bit levels into the first printing information.

19. The image processing module of claim 16, wherein the printer is a laser printer and the first printing information are pulse widths of a laser signal, and the second printing information are pulse time offsets of the laser signal.

20. The image processing module of claim 16, wherein the printer is an inkjet printer and the first printing information are drop sizes and second printing information determine drop positions.

21. The image processing module of claim 16, wherein the color arranging unit calculates the second printing information used to determine the arrangement of the dots in the printing cell according to a predetermined order of the printing colors.

22. The image processing module of claim 16, wherein the color arranging unit calculates the second printing information used to determine the arrangement of the dots in the printing cell in order of the printing colors determined by magnitudes of the corresponding first printing information.

23. A dot arranging unit to determine positions of dots corresponding to printing colors in a cell of a pixel lattice, the dot arranging unit comprising:
a positioning module to calculate parameters controlling positions of centers of the dots in the cell based on sizes of the dots and a number of dots to be positioned in the cell so that an overlap of the dots is minimized.

24. The dot arranging unit of claim 23, wherein if the size of only one of the dots is not zero, the positioning module calculates parameters controlling the position of the center of the one dot so that the one dot is placed in a center of the cell.

25. The dot arranging unit of claim 23, wherein if sizes of only two of the dots are not zero, the positioning module calculates parameters controlling the positions of the centers of the only two dots to maximize a distance between the centers of the two dots.

26. The dot arranging unit of claim 23, wherein if the sizes of more than two of the dots are not zero, the positioning module calculates parameters controlling the positions of the centers of the more than two dots according to a predetermined order of the corresponding printing colors.

27. An image multitoning apparatus, comprising:
a color component divider to divide an input color image into at least two color component layers corresponding to printing colors;
a halftone processor to convert the at least two color component layers into corresponding halftone images comprising color values within a range of color levels; and
a printing engine to calculate sizes of color dots to be printed according to the halftone images and to calculate color dot positions of the color dots based on the sizes of the color dots such that an overlap of the color dots is minimized.

28. The image multitoning apparatus of claim 27, further comprising:
a printing unit to print an image corresponding to the input color image based on the calculated color dot sizes and positions on a recording medium.

29. The multitoning apparatus of claim 27, wherein the printing engine comprises:
a dot size calculating unit to calculate the sizes of the color dots according to the halftone images;
a color component number determination unit to determine a number of color dots with non-zero sizes for each pixel; and
a dot position calculating unit to calculate the color dot positions based on the color dot sizes and the number of color dots with non-zero sizes.

30. The multitoning apparatus of claim 27, wherein the input color image is a non-CMYK color image.

31. The multitoning apparatus of claim 27, wherein the color component layers comprise a plurality of N-bit color brightness values corresponding to a plurality of pixels.

32. A method of converting a color input image into printing information, the method comprising:
generating color component images from the color input image, each color component image corresponding to a printing color of a printer;
converting color values of the color component images into first printing information used to determine sizes of dots of the respective printing color to be arranged in printing cells; and
calculating second printing information used to determine an arrangement of the dots in each printing cell so that an overlap of the dots is minimized.

33. A method of minimizing color dots overlapping in a color printer, the method comprising: calculating parameters controlling positions of centers of color dots in printing cells of a pixel lattice based on sizes of the color dots so that to minimize an overlap of the color dots.

34. A computer readable medium having executable codes to perform a method to minimize an overlap of color dots in a printing output, the method comprising:
dividing an input color image into at least two color component layers corresponding to printing colors;
converting the at least two color component layers into corresponding halftone images comprising color values within a range of color levels; and
calculating sizes of color dots to be printed according to the halftone images and to calculate color dot positions of the color dots based on the sizes of the color dots such that an overlap of the color dots is minimized.

35. An image forming apparatus, comprising:
a print unit to print printing data; and
an image multitoning apparatus in communication with the print unit to divide an input color image into at least two color component layers corresponding to printing colors, to convert the at least two color component layers into corresponding halftone images comprising color values within a range of color levels, to calculate sizes of color dots to be printed according to the halftone images and to calculate color dot positions of the color dots based on the sizes of the color dots such that an overlap of the color dots is minimized, and to output the printing data with the positioned color dots to the print unit.
